(19) United States
(12) Patent Application Publication
(10) Pub. No.: US 2025/0175189 A1
(43) Pub. Date: May 29, 2025

(54) READOUT-CIRCUIT

(71) Applicants: TRINAMIX GMBH, Ludwigshafen Am Rhein (DE); CONSEJO SUPERIOR DE INVESTIGACIONES CIENTIFICAS (CSIC), Madrid (ES); UNIVERSITAT AUTONOMA DE BARCELONA, Barcelona (ES)

(72) Inventors: Darren GOULD, Ludwigshafen am Rhein (DE); Francesc SERRA GRAELLS, Barcelona (ES); Alejandro SUANES, Barcelona (ES)

(21) Appl. No.: 18/842,853

(22) PCT Filed: Mar. 9, 2023
(86) PCT No.: PCT/EP2023/055956

§ 371 Date: Aug. 30, 2024

(30) Foreign Application Priority Data
Mar. 10, 2022 (EP) 22382230.5

(51) Int. Cl. H03M 1/60; G01J 1/44

(52) U.S. Cl. CPC H03M 1/60; G01J 1/44

(57) ABSTRACT

Disclosed herein is a readout-circuit. The readout-circuit is configured for converting an analog sensor charge into a digital output count. The readout-circuit includes at least one integrate-and-fire(IAF)-circuit. The IAF-circuit is configured for converting the analog sensor charge into a first digital output count. An analog voltage remainder after a final IAF cycle is further processed. The readout-circuit includes at least one analog-to-digital-converter (ADC). The ADC is configured for converting the analog voltage remainder into a second digital output. Further, disclosed herein are a photodetector and a method for readout of an analog sensor charge.

### TECHNICAL FIELD

The invention relates to a readout-circuit configured for converting an analog sensor charge into a digital output count, a photodetector and a method for readout of an analog sensor charge. Specifically, the readout-circuit may be used for reading out photodetectors such as photodetectors used in a spectrometer. More specifically, the readout-circuit may be used for determining a digital output count of photoconductors such as lead sulfide photoconductors or photodiodes such as Si, InGaAs or SiGe. Other options may also be feasible.

### BACKGROUND ART

Spectrometry generally requires separating radiation into spectral wavelength components and measuring the intensity of each component. One approach to spectrometry may perform the measurement in parallel using an array of sensors which react to radiation that has been separated into many spectral wavelength components. Many sensor technologies can be used to enable spectroscopy including lead sulfide (PbS), lead selenide (PbSe), indium gallium arsenide (InGaAs), pyroelectric and others. Most of these sensor technologies may require measuring small amounts of electrical charge with high resolution. Electronics first may convert the electrical charge from the sensor array into voltage in the read-out-integrated-circuit (ROIC). The voltage may be then digitized using an analog-to-digital converter (ADC). These two integrated circuits may be usually expensive and require significant power. In addition, using a separate ROIC and ADC may require extra circuitry and long connection lengths between the ROIC analog output and the ADC input. These connections may be vulnerable to noise pickup from both internal and external sources.

It is known to use ROICs and ADCs to convert the charge to voltage and then digitize. Most parallel charge to voltage conversion ROICs use a charge amplifier circuit, exploiting the linear relationship between accumulated charge and voltage on a capacitor. This type of circuit may be used due to the flexibility offered to adjust the output voltage according to application requirements and inputs, the ability to measure and resolve small charges and the ability to realize the circuit within most existing mixed signal IC foundry processes. The ROIC may convert the charge (Q) from the sensor to voltage (V) by collecting the charge on a capacitor (C) according to the equation

$$V = - \frac{Q}{C} .$$

The maximum voltage may be limited by the IC technology and so the charge-capacitance product must be kept below this limit. The flexibility of the ROIC may allow a voltage output to be adjusted for use in many different applications. Regardless of the maximum charge dictated by the sensor and application, the output can be adjusted to utilize a large percentage of the maximum voltage dictated by the IC. Two methods can be used to control the charge and adjust the charge-to-voltage gain which maximizes the output voltage:
1) adjustment of the capacitor value to increase or decrease the voltage to charge conversion ratio and/or
2) adjustment of the charge by changing the integration time t since the charge is related to sensor current i(t) with

$$Q = {\int }_{0}^{t} i ( t ) dt .$$

Multiple capacitor values tend to be implemented within an IC for every channel. A user can select a capacitive value and can adjust the integration time according to the application. The capacitor ranges tend to be between several tens of femto-Farads and several tens of pico-Farads. The smaller capacitors increase the output voltage for a constant charge by increasing the charge-to-voltage gain. The lower limit of the capacitance is dictated by the IC technology. The larger capacitors may require a large area on the IC but will increase dynamic range and decrease the charge-to-voltage gain.

Noise of the measurement may be limited by three factors:
1) a sensor current noise;
2) a noise due to the ROIC;
3) a quantization noise of the ADC.

For all applications, it may be desirable to allow the noise of the sensor to dominate the noise floor. Thus, the noise due to the ROIC and the quantization noise should be kept significantly lower than that of the sensor. For this architecture, the analog voltage output of the charge converters may be connected to the ADC. The ADC may be located within the integrated circuit or as a separate integrated circuit. In either case, the channels tend to be multiplexed and transferred serially due to the large number of signals. The extra circuitry may be required for multiplexing and the relatively long length of the connections means that this type of architecture may be vulnerable to analog noise pickup from other internal or external sources.

Moreover, the complexity, size and power of an ADC increase rapidly with bit count. In order to decrease overall power, cost and size, a single high-resolution ADC tends to be used with a high sampling rate as opposed to using multiple high-resolution ADCs with lower sampling rates.

A different approach has been commercialized for use with other charge-based sensor array systems. This approach is exemplified by the publication of Dei, Michele, et al. “Highly linear integrate-and-fire modulators with soft reset for low-power high-speed imagers.” 2017 IEEE International Symposium on Circuits and Systems (ISCAS). IEEE, 2017 and is known as an integrate-and-fire circuit (IAF-circuit). The linear nature of the charge-to-voltage conversion using capacitors may be employed. It is, however, modified to directly convert the analog current to a digital signal. The capacitor and the maximum voltage may be reduced in order to allow the charge to saturate the output. A circuit may detect the saturation and automatically resets the charge-to-voltage conversion. A counter may be simultaneously increased by 1 for every saturation event. The saturation and counting may continue during the integration cycle and the counter value, after the integration time ends, is proportional to the input current.

Digital output may be generated locally by a measurement cell and no separate ADC may be required. In fact, every measurement cell may directly digitize the signal as a counter value. The analog signal path may be short, and the circuit may run without a clock, i.e. asynchronously, which further reduces noise sources. The integration capacitor can be reduced in order to increase the number of saturation events. The area required for the capacitors may be thus much smaller and the measurement cell can be made smaller. Several capacitors are still typically included to allow the user to adjust the gain. The integration time may remain to allow the user full control over gain and maximization of the resolution. The ADC can likewise be replaced with a relatively small counter and Schmitt trigger circuit along with other logic gates. Such a circuit may require comparatively little area and power and may be replicated for every sensor input. Due to the nature of the circuit, it may be smaller and much more energy efficient. Power may be on the order of ten μW per channel using modern CMOS mixed signal processes. The size of the circuit may be likewise reduced because the size of the capacitor can be decreased and the ADC can be replaced by a counter and Schmitt-Trigger.

Despite the advantages achieved in the prior art, various technical challenges still remain. Specifically, there is a need for reducing size, complexity, cost and power consumption of a parallel charge to digital conversion and further for decreasing an overall noise of the system. Further, for IAF-circuits, charges must be large enough in order to generate enough counts during the integration to achieve a high-resolution on the measurement signal. To achieve a 16-bit resolution, more than 65 k counting events would be required. As one example, with a minimum capacitance of 25fF and a saturation voltage of 0.5V, a charge of 820pC would be required to achieve a 16-bit resolution. Thus, for sensors that generate small currents, IAF-circuits typically do not generate enough digital resolution.

### Problem to be Solved

It is therefore desirable to provide a readout-circuit, a photodetector and a method for readout of an analog sensor charge which overcome the above-mentioned disadvantages of known devices and methods of similar kind. Specifically, the devices and methods shall be suited for reducing size, complexity, cost, power consumption and noise of readout-circuits, specifically for photodetectors, while still ensuring a reliable and accurate readout, specifically also of small analog sensor charges.

### SUMMARY

This problem is addressed by a readout-circuit, a photodetector and a method for readout of an analog sensor charge with the features of the independent claims. Advantageous embodiments which might be realized in an isolated fashion or in any arbitrary combinations are listed in the dependent claims as well as throughout the specification.

In a first aspect of the present invention, a readout-circuit is disclosed.

The term “readout” as used herein is a broad term and is to be given its ordinary and customary meaning to a person of ordinary skill in the art and is not to be limited to a special or customized meaning. The term specifically may refer, without limitation, to an action or process of quantifying and/or processing at least one physical property and/or a change in at least one physical property detected by at least one device, specifically by at least one measurement device such as at least one sensor. The measurement device may specifically comprise at least one photodetector. The photodetector may specifically comprise at least one light-sensitive region. The readout may comprise an individual readout of one device such as of one sensor. Additionally or alternatively, the readout may comprise a readout of a group of devices such as a group of sensors. The term “readout-circuit” as used herein is a broad term and is to be given its ordinary and customary meaning to a person of ordinary skill in the art and is not to be limited to a special or customized meaning. The term specifically may refer, without limitation, to an electric circuit configured for quantifying and/or processing at least one physical property and/or a change in at least one physical property detected by at least one measurement device such as a sensor. The readout-circuit may be configured for reading out at least one sensor. Specifically, the readout-circuit may be configured for reading out at least one photodetector or at least one sensor of the photodetector.

The term “sensor” as used herein is a broad term and is to be given its ordinary and customary meaning to a person of ordinary skill in the art and is not to be limited to a special or customized meaning. The term specifically may refer, without limitation, to an arbitrary element or device configured for detecting at least one condition or for measuring at least one measurement variable. As an example, the sensor may be a light-sensitive sensor as e.g. used in a photodetector. However, other options are also feasible. Specifically, the sensor may be capable of generating at least one signal, such as a measurement signal, which is a qualitative or quantitative indicator of the measurement variable and/or measurement property, e.g. of an illumination of the sensor. The signal may be or comprise an electrical signal, such as a current or a charge.

The term “photodetector” as used herein is a broad term and is to be given its ordinary and customary meaning to a person of ordinary skill in the art and is not to be limited to a special or customized meaning. The term specifically may refer, without limitation, to a measurement device configured for detecting optical radiation, such as for detecting an illumination and/or a light spot generated by at least one light beam. The photodetector may be and/or may comprise a photoconductor or a photodiode. The photodetector may comprise at least one substrate. A single photodetector may be a substrate with at least one single light-sensitive region, which generates a physical response to the illumination for a given wavelength range. The photodetector comprises at least one sensor configured for generating an analog sensor charge dependent on an illumination of a light-sensitive region of the sensor.

The term “light-sensitive region” as used herein is a broad term and is to be given its ordinary and customary meaning to a person of ordinary skill in the art and is not to be limited to a special or customized meaning. The term specifically may refer, without limitation, to an area being sensitive to an illumination, e.g. by an incident light beam. For example, the light-sensitive region may be a two-dimensional or three-dimensional region which preferably, but not necessarily, may be continuous and/or may form a continuous region. The light-sensitive region may comprise at least one photoconductive material selected from the group consisting of lead sulfide (PbS); lead selenide (PbSe); mercury cadmium telluride (HgCdTe); cadmium sulfide (CdS); cadmium selenide (CdSe); indium antimonide (InSb); indium arsenide (InAs); indium gallium arsenide (InGaAs); silicon (Si); Silicon Germanium (SiGe); extrinsic semiconductors, organic semiconductors. Specifically, the photodetector may comprise a plurality of sensors, wherein the sensors may be arranged in an array.

The term “light” as used herein is a broad term and is to be given its ordinary and customary meaning to a person of ordinary skill in the art and is not to be limited to a special or customized meaning. The term specifically may refer, without limitation, to electromagnetic radiation in one or more of the visible spectral range, the ultraviolet spectral range and the infrared spectral range. Therein, in partial accordance with standard ISO-21348, the term visible spectral range generally refers to a spectral range of 380 nm to 760 nm. The term infrared (IR) spectral range generally refers to electromagnetic radiation in the range of 760 nm to 1000 μm, wherein the range of 760 nm to 1.4 μm is usually denominated as the near infrared (NIR) spectral range, and the range from 15 μm to 1000 μm as the far infrared (FIR) spectral range. The term “ultraviolet spectral range” generally refers to electromagnetic radiation in the range of 1 nm to 380 nm, preferably in the range of 100 nm to 380 nm. The term “light” may also be denoted as “illumination”. Preferably, illumination as used within the present invention is visible light, i.e. light in the visible spectral range, and/or infrared light, i.e. light in the infrared spectral range.

The light-sensitive region may be illuminated by at least one illumination source. The illumination source can for example be or comprise an ambient light source and/or may be or may comprise an artificial illumination source. By way of example, the illumination source may comprise at least one infrared emitter and/or at least one emitter for visible light and/or at least one emitter for ultraviolet light. By way of example, the illumination source may comprise at least one light emitting diode and/or at least one laser diode. The illumination source can comprise in particular one or a plurality of the following illumination sources: a laser, in particular a laser diode, although in principle, alternatively or additionally, other types of lasers can also be used; a light emitting diode; an incandescent lamp; a neon light; a flame source; an organic light source, in particular an organic light emitting diode; a structured light source. Alternatively or additionally, other illumination sources can also be used.

The illumination source may be an arbitrary light source having at least one radiating wavelength having an overlap to the sensitive wavelength of the photodetector. The illumination source generally may be adapted to emit light in at least one of: the ultraviolet spectral range, the infrared spectral range. Most preferably, at least one illumination source is adapted to emit light in the NIR and IR range, preferably in the range of 800 nm and 5000 nm, most preferably in the range of 1000 nm and 4000 nm. The illumination source may comprise at least one non-continuous light source. The illumination source may be configured for generating at least one modulated light beam. Alternatively, the illumination source may comprise at least one continuous light source. The light beam generated by the illumination source may be non-modulated and/or may be modulated by further optical means.

The readout-circuit is configured for converting an analog sensor charge into a digital output count. The readout-circuit comprises at least one integrate-and-fire(IAF)-circuit. The IAF-circuit is configured for converting the analog sensor charge into a first digital output count. The readout-circuit is further configured for processing an analog voltage remainder after a final IAF cycle. The readout-circuit comprises at least one analog-to-digital-converter (ADC). The ADC is configured for converting the analog voltage remainder into a second digital output.

The term “analog signal” as used herein is a broad term and is to be given its ordinary and customary meaning to a person of ordinary skill in the art and is not to be limited to a special or customized meaning. The term specifically may refer, without limitation, to a continuous progression of a physical quantity. The term “analog sensor charge” as used herein is a broad term and is to be given its ordinary and customary meaning to a person of ordinary skill in the art and is not to be limited to a special or customized meaning. The term specifically may refer, without limitation, to continuous progression in time of charge. As an example, the analog sensor charge may continuously vary over time by building up, e.g. due to an illumination of a light-sensitive region of the photodetector. Additionally or alternatively, the analog sensor charge may for example continuously vary over time by dissipating, e.g. due to being transferred to further electrical components.

The term “digital” as used herein is a broad term and is to be given its ordinary and customary meaning to a person of ordinary skill in the art and is not to be limited to a special or customized meaning. The term specifically may refer, without limitation, to a finite or at least countable set of quantized or discrete signal values. The term “digital output count” as used herein is a broad term and is to be given its ordinary and customary meaning to a person of ordinary skill in the art and is not to be limited to a special or customized meaning. The term specifically may refer, without limitation, to a digital count or digital census given out by the readout-circuit. Specifically, the digital output count may be a count or a census using at least one of natural numbers, whole numbers and integers. As an example, the digital output count may start at 0 and increment by 1 for each event inducing a count, e.g. an illumination of a light-sensitive region of the photodetector with a certain intensity. The digital output count may be given out in a Boolean domain, such as by using binary digits also referred to as bits. Other options may also be feasible. The digital output may be given out to at least one processor for further processing, e.g. for evaluating at least one sensor signal for generating measurement data displayable to a user.

The readout-circuit comprises at least one integrate-and-fire-circuit (IAF-circuit). The term “integrate-and-fire-circuit”, also referred to as IAF-circuit, as used herein is a broad term and is to be given its ordinary and customary meaning to a person of ordinary skill in the art and is not to be limited to a special or customized meaning. The term specifically may refer, without limitation, to an electric circuit configured for integrating an incoming analog sensor charge, e.g. by using an integrator, and firing an event signal, e.g. by using a comparator, when an output voltage reaches a predefined quantization threshold. The event can be used to reset the integrator in order to start again with the integration of the incoming analog sensor charge. The incoming analog sensor charge e.g. may be based on at least one capacitive trans-impedance amplifier (CTIA). Different types of IAF-circuits are generally known to the skilled person, e.g. from the publication Dei, Michele, et al. “Highly linear integrate-and-fire modulators with soft reset for low-power high-speed imagers.” 2017 IEEE International Symposium on Circuits and Systems (ISCAS). IEEE, 2017, which is included here in its entirety. Without limitation, specific embodiments of the IAF-circuit will also be outlined below in further detail.

The IAF-circuit is configured for converting the analog sensor charge into a first digital output count.

The IAF-circuit may comprise at least one integrator. The term “integrator” as used herein is a broad term and is to be given its ordinary and customary meaning to a person of ordinary skill in the art and is not to be limited to a special or customized meaning. The term specifically may refer, without limitation, to an electric circuit configured for integrating at least one input signal, specifically over time. In other words, the integrator may be configured for accumulating the input signal over time. Specifically, the integrator may be a current integrator. The integrator may be configured for measuring the analog sensor charge. The integrator may comprise at least one of an operational amplifier and a capacitor. The operational amplifier may be an inverted operational amplifier. The operational amplifier and the capacitor may be connected in parallel. The IAF-circuit may specifically comprise at least one capacitor, wherein the IAF-circuit may be configured for employing a linear nature of a charge-to-voltage conversion using the capacitor. The integrator may comprise at least one mixed signal circuit, specifically for resetting the integrator. The integrator may comprise at least on charge amplifier. Further options are feasible and are generally known to the skilled person.

An input of the operational amplifier may be held to a known voltage V_{ref}. The integrator may be configured for resetting an output of the operational amplifier to V_{ref} after each saturation event. The integrator may be configured for integrating the output of the operational amplifier between the reference voltage V_{ref} and a comparator voltage V_{comp} for determining an integration voltage Vᵢₙₜ. The output of the operational amplifier Vᵢₙₜ may be thus V_{ref}≥Vᵢₙₜ≥V_{comp}.

The term “integration voltage”, also referred to as Vᵢₙₜ, as used herein is a broad term and is to be given its ordinary and customary meaning to a person of ordinary skill in the art and is not to be limited to a special or customized meaning. The term specifically may refer, without limitation, to a voltage output generated by the integrator, specifically by the operational amplifier of the integrator.

The term “reference voltage”, also referred to as V_{ref}, as used herein is a broad term and is to be given its ordinary and customary meaning to a person of ordinary skill in the art and is not to be limited to a special or customized meaning. The term specifically may refer, without limitation, to a predefined voltage serving as a reference, specifically for the integrator. The reference voltage may specifically be applied to the operational amplifier of the integrator, specifically to a first input of the typically two inputs of the operational amplifier. The analog sensor charge may specifically be fed into a second input of the operational amplifier. An output of the operational amplifier may further be fed back into the second input, specifically via the capacitor.

The term “comparator voltage”, also referred to as V_{comp}, as used herein is a broad term and is to be given its ordinary and customary meaning to a person of ordinary skill in the art and is not to be limited to a special or customized meaning. The term specifically may refer, without limitation, to a predefined voltage serving as a reference or threshold, specifically for the comparator.

Generally, the terms “first”, “second” and, if applicable, further numberings are merely used herein as nomenclature, without indicating an order or ranking. Specifically, a first entity may be different to a second entity. However, the first entity and the second entity may also at least partially comprise each other or may also at least be of the same type.

The IAF-circuit may further comprise at least one comparator configured for determining a saturation event. The comparator may be configured for comparing Vᵢₙₜ with V_{comp}. Specifically, the comparator may be configured for detecting when Vᵢₙₜ is equal to V_{comp}. The comparator may be configured for generating an event signal, also denoted as event, each time Vᵢₙₜ crosses V_{comp}. The term “comparator” as used herein is a broad term and is to be given its ordinary and customary meaning to a person of ordinary skill in the art and is not to be limited to a special or customized meaning. The term specifically may refer, without limitation, to an electric circuit configured for comparing at least two input signals, specifically voltages. The comparator may be configured for generating at least one output signal, specifically a digital output signal, indicating a result of the comparison, e.g. which input signal is larger. As an example, the comparator may generate as an output “HIGH” or “1” in the case that a first input voltage is higher than a second input voltage and “LOW” or “0” in the case that the first input voltage is lower than the second input voltage. The output signal may be generated continuously over time, specifically for varying input signals.

The comparator may be and/or may comprise at least one Schmitt-trigger. The Schmitt-trigger may be an inverting or a non-inverting Schmitt-trigger. The term “Schmitt-trigger” as used herein is a broad term and is to be given its ordinary and customary meaning to a person of ordinary skill in the art and is not to be limited to a special or customized meaning. The term specifically may refer, without limitation, to a comparator circuit in which switch-on and switch-off thresholds are offset from each other by a switching hysteresis. The Schmitt-trigger may be configured for comparing an input voltage, specifically a voltage varying over time, with two threshold voltages, an upper threshold voltage and a lower threshold voltage. Specifically, the Schmitt-trigger may be configured for giving out HIGH or 1 in case the input voltage is higher than the upper threshold voltage and LOW or 0 in case the input voltages is lower than the lower threshold voltage, wherein the Schmitt-trigger may further be configured for maintaining a preceding output between the upper threshold voltage and the lower threshold voltage. In other words, as long as the input voltage does not exceed one of the two threshold voltage, an output of the Schmitt-trigger may not be altered. However, other options for a comparator are also feasible.

The output of the operational amplifier may begin at the known voltage V_{ref} upon reset. The output of the operational amplifier may decrease as the charge from the sensor is integrated. The output of the operational amplifier may be connected to a comparator V− input. When the output of the operational amplifier/comparator V− input drops below a comparator V+ terminal, a comparator output may toggle HIGH. The toggling of the comparator may trigger a reset circuit that pulls the output of the operational amplifier back to the initial voltage state V_{ref} such that the integration cycle can begin again. The comparator output change to HIGH may be the saturation event that triggers resetting of the integrator. The comparator output change may, in particular simultaneously, increase a counter value by 1. In this manner, the integration cycles may be counted. Each finished integration cycle may increment the first digital output count by 1.

The term “saturation event” as used herein is a broad term and is to be given its ordinary and customary meaning to a person of ordinary skill in the art and is not to be limited to a special or customized meaning. The term specifically may refer, without limitation, to an occurrence of a saturation or a satiation of an electric component, specifically of the integrator, more specifically of the capacitor of the integrator.

The integration capacitor value affects the frequency of saturation events in the system. A smaller capacitor thus produces a higher number of saturation events per second compared to a larger capacitor. Thus, for the same charge, a smaller capacitor will count more events than a larger capacitor. A capacitance of the capacitor may be defined by the size of the capacitor, e.g. by a ratio of an area of capacitor plates divided by a distance between the capacitor plates. The occurrence of a saturation event may refer to a finished integration cycle of the integrator.

The IAF-circuit may further comprise at least one counter configured for determining the first digital output count by counting the saturation events. The term “counter” as used herein is a broad term and is to be given its ordinary and customary meaning to a person of ordinary skill in the art and is not to be limited to a special or customized meaning. The term specifically may refer, without limitation, to an electric circuit configured for counting events. In other words, the counter may be configured for storing a number of times a particular event has occurred. Specifically, for each determined saturation event, the counter may be incremented by 1. The counter may comprise at least one output. The counter may be configured for giving out the count or, in other words, the number of times a particular event has occurred, specifically in a binary number system. Other options are feasible. The counter may comprise at least one input. An input of the counter may be connected to the above-described comparator. A further input of the counter may be connected to a clock, specifically a global clock of a system, such as the readout-circuit. The counter may comprise a plurality of flip-flops connected in a cascade. The counter may be a synchronous counter. The flip-flops may be simultaneously triggered by the clock. However, the counter may also be an asynchronous counter. Other options are feasible and are generally known to the skilled person. The first digital output count, also denoted as IAF digital output, may represent a whole number of saturation events for a given input charge. The first digital output count may be proportional to a whole number of integration cycles. Specifically, the counter of the IAF-circuit may be a most significant bits (MSB) counter. The MSB counter may be configured for determining the most significant bits of an output of the readout-circuit. The readout-circuit may comprise at least one switch for resetting the MSB counter. For example, the MSB counter may comprise a reset pin to reset the count back to 0.

The IAF-circuit may further comprise at least one mixed signal circuit configured for resetting the output of the operational amplifier Vᵢₙₜ to V_{ref} after each saturation event. The mixed signal circuit may be connected in parallel to the integrator or the capacitor of the integrator generating a short circuit when closed. The mixed signal circuit may be an electrical switch or an electromechanical switch. Specifically, the mixed signal circuit may comprise at least one transmission gate. The reset of the output of the operational amplifier may be a critical component of the IAF. The IAF-circuit may be configured to ensure that the reset happens quickly and automatically after each saturation event. The analog voltage needs to be consistently returned to V_{ref} after every event.

As outlined above, the comparator may be configured for determining a saturation event when Vᵢₙₜ reaches V_{comp} and for firing an event signal. However, at the final integration cycle, also denoted as final IAF cycle, of integrating the incoming analog sensor charge, there may be a remainder which, because the integrated voltage does not reach the quantization threshold V_{comp} (Vᵢₙₜ>V_{comp}), cannot trigger firing an event and, thus, is not counted. The term “analog voltage remainder” as used herein is a broad term and is to be given its ordinary and customary meaning to a person of ordinary skill in the art and is not to be limited to a special or customized meaning. The term specifically may refer, without limitation, to a remainder or a rest or a residual which is left after a complete processing of the analog sensor charge by the IAF-circuit, specifically at the end of the final finished integration cycle. The remainder may be one or more of characterized, described or quantified by using at least one analog voltage. The analog voltage remainder may refer to a remainder of a final unfinished integration cycle.

The readout-circuit is configured for processing an analog voltage remainder after a final IAF cycle. The IAF-circuit may be configured for digitizing the analog sensor charge at least up to the analog voltage remainder. The term “digitizing”, including any grammatical variation thereof, as used herein is a broad term and is to be given its ordinary and customary meaning to a person of ordinary skill in the art and is not to be limited to a special or customized meaning. The term specifically may refer, without limitation, to a process of converting or transferring at least one analog input signal, specifically an analog sensor charge, into at least one digital output signal, specifically a digital output count. The digitizing may comprise detecting and/or quantifying the analog input signal, specifically in order for subsequently converting it. The non-digitizable remainder may be an entity which is not detectable and/or not quantifiable by the IAF-circuit. An unfinished integration cycle may specifically not be quantifiable by the IAF-circuit and thus not be digitizable by the IAF-circuit, whereas a finished integration cycle may be digitizable by incrementing a counter of the IAF-circuit. As an example, an analog sensor charge may not be high enough for generating a finished integration cycle in the IAF-circuit, such that the analog sensor charge as a whole may not be digitizable. Thus, specifically for small analog sensor charges, the IAF-circuit may not be sufficient.

The readout-circuit further comprises at least one analog-to-digital-converter (ADC) configured for converting the analog voltage remainder into a second digital output. The term “second digital output” as used herein is a broad term and is to be given its ordinary and customary meaning to a person of ordinary skill in the art and is not to be limited to a special or customized meaning. The term specifically may refer, without limitation, to an arbitrary digital output generated by the ADC proportional to the remainder voltage of the final uncompleted integration cycle. For example, the second digital output may be a digital output count. However, other options are feasible. The second digital output may be proportional to the remainder voltage of the final but uncompleted integration cycle. The ADC may be a counter of least significant bits (LSB), also denoted as LSB counter. The LSB counter may be configured for determining the least significant bits of an output of the readout-circuit.

The readout-circuit may be configured for determining a combined digital output count by combining the first digital output count and the second digital output. A combined digital output count may be given out in the binary number system. The IAF-circuit may be configured for determining the most significant bits (MSB) and the ADC may be configured for determining the least significant bits. The counter of the IAF-circuit may also be referred to a MSB counter and the counter of the ADC may also be referred to as LSB counter. The M-bits of the MSB counter may represent the number of completed integration cycles and the N-bits of the LSB counter may represent the binary completed value of the remainder voltage on the IAF. The combined digital value of MSB concatenated with LSB may represent a N+M bit digital resolution. The readout-circuit may comprise at least one output unit or at least one interface. The output unit may be configured for generating at least one output, specifically at least one digital output voltage signal, such as the combined digital output count. The output unit may be configured for passing the output to at least one external device or element, e.g. to a processor for further evaluation. As an example, the output unit may be configured for identifying or marking the most significant bits and/or the least significant bits, such that e.g. a processor can assign them correctly. Further options are feasible.

The readout-circuit further comprises at least one analog-to-digital-converter (ADC). The ADC is configured for converting the analog voltage remainder into a second digital output. The term “analog-to-digital-converter”, also referred to as ADC, as used herein is a broad term and is to be given its ordinary and customary meaning to a person of ordinary skill in the art and is not to be limited to a special or customized meaning. The term specifically may refer, without limitation, to an electric circuit configured for converting or transferring at least one analog input signal, specifically an analog sensor charge, into at least one digital output signal, specifically a digital output count. Any known ADC architecture may be used as ADC for converting the analog voltage remainder into a second digital output. For example, the ADC may comprise at least one ADC architecture selected from the group consisting of a counter type ADC, a single-slope ADC, a dual-slope ADC, a pipelined ADC, a successive-approximation (SAR) ADC, a sigma-delta ADCs. With respect to embodiments of the ADC reference is made to “Analog-to-Digital Converter Architectures and Choices for System Design” by Brian Black, Analog Dialogue 33-8 (1999). The ADC may have a low resolution, specifically 14-bit or less, more specifically 10-bit or less. Using a simple ADC requiring only little power supply and only little area may be possible.

For example, the ADC may be a counter type ADC, also referred to as counter ADC or slope ADC or slope converter. However, as outlined above, other options are feasible and are generally known to the skilled person. The ADC may specifically comprise at least one of a comparator, specifically a Schmitt-trigger, and a counter. A V+ terminal of the comparator may be ramped via a DAC from V_{comp} to Vᵢₙₜ in 2^{N} steps. During ramping, the V_{comp} voltage may cross the Vᵢₙₜ remainder voltage and the comparator output may be triggered. At this point, a counter may be activated and every remaining V+ step from the DAC increments the counter. The final count on the counter may be a digitized representation of the voltage remainder Vᵢₙₜ. The readout-circuit may comprise at least one switch for resetting the counter. For example, the counter may comprise a reset pin to reset the count back to 0. Using a counter type ADC may allow sharing the comparator circuitry. The ADC and the IAF-circuit may share at least one component, specifically the at least one comparator. Specifically, the ADC and the IAF-circuit may share the above-mentioned Schmitt-trigger. For example, the Schmitt-trigger connected to the integrator of the IAF-circuit may also be used as part of the ADC. An input of the counter of the ADC may then be connected to the output of the Schmitt-trigger. A further input of the counter of the ADC may specifically be connected to a clock, specifically a global clock of the readout-circuit.

The readout-circuit may further comprise at least one event handler. The event handler may be configured for identifying events generated by the comparator. The event handler, based on the events, may be configured for initiating reset of the integrator such as by initiating the mixed signal circuit. The event handler, based on the events, may be configured for initiating the IAF counters. The event handler, based on the events, may be configured for initiating the circuitry for digitizing the analog voltage remainder, in particular in case of using a counter ADC. The event handler may be preconnected to the counter of the ADC and/or the counter of the IAF-circuit. The event handler may be configured for assigning the output of the Schmitt-trigger to the counter of the ADC and/or the counter of the IAF-circuit.

When the integration at the IAF-circuit completes, there may exist an analog voltage remainder Vᵢₙₜ at the output of the operational amplifier such that V_{ref}≥Vᵢₙₜ>V_{comp}. The IAF-circuit may trigger automatically an IAF reset in case Vᵢₙₜ crosses V_{comp}. The remainder voltage may be the leftover voltage that has not triggered an IAF reset. The analog voltage remainder may be quantized by the ADC to yield a value representing the binary percent completion of the operational amplifier output voltage. A binary value of 0 would represent the voltage Vᵢₙₜ and the binary value 2^{N}−1 would represent the value V_{comp}, where N is the number of bits of resolution for the ADC. ADC values between 0 and 2^{N}−1 may represent the analog voltage remainder.

The readout-circuit may be configured for readout of a small analog sensor charge, specifically an analog sensor charge of less than 1nC, more specifically of less than 1pC. As explained, specifically by using the ADC for determining the LSB, also a small analog sensor charge may be digitized which does not trigger a saturation event at the integrator of the IAF-circuit. This may specifically be relevant with respect to a readout of photodetectors or, more specifically, individual sensors of photodetectors, which may generate only small photocurrents. The readout-circuit may be configured for readout of at least one sensor configured for generating the analog sensor charge dependent on an illumination of a light-sensitive region of the sensor.

The readout-circuit may be configured for readout of a plurality of sensors configured for generating the analog sensor charge dependent on an illumination of a light-sensitive region of the sensor. The sensors may be arranged in an array. The term “array” as used herein is a broad term and is to be given its ordinary and customary meaning to a person of ordinary skill in the art and is not to be limited to a special or customized meaning. The term specifically may refer, without limitation, to a spatial arrangement of elements such as sensors. The array may be a one-dimensional array, e.g. a sensor sequence along an axis, or a two-dimensional array, e.g. a sensor matrix. The array may also be a three-dimensional array. The array may be a regular array, e.g. comprising constant distances between elements. The array may be an irregular array, e.g. comprising different distances between elements. The elements within the array may be of the same type or of a different type. As an example, the array may comprise sensors which are light-sensitive for different wavelengths. Further options are feasible.

The readout-circuit may be a readout integrated circuit (ROIC). The readout-circuit may be an integrated circuit (IC), also referred to as chip or microchip, or the readout-circuit may at least form a part of an IC. As the skilled person will know, an IC typically comprises at least one electric circuit assembled on a substrate, specifically a semiconductor substrate, more specifically a silicon (Si) substrate. The readout-circuit may be configured for accumulating at least one sensor current, specifically a photocurrent, wherein the accumulating of the sensor current may generate an analog sensor charge. As an example, the readout-circuit may be configured for accumulating a photocurrent for each sensor of a photodetector or for groups of sensors of the photodetector.

The readout-circuit may be configured for storing or at least for buffering the analog sensor charge. The readout-circuit may be configured for transferring the analog sensor charge to at least one output, e.g. an output of an IC, wherein the output may specifically be a digital output. The readout-circuit may be a digital readout integrated circuit (DROIC). The DROIC may use on-chip analog-to-digital conversion, specifically for digitizing at least one accumulated photocurrent. The readout-circuit may be a digital pixel readout integrated circuit (DPROIC). The DPROIC uses on-chip analog-to-digital conversion within each pixel or group of pixels, specifically for digitizing at least one accumulated photocurrent, wherein a pixel may specifically refer to a sensor of a photodetector.

In a further aspect of the present invention, a photodetector is disclosed. The photodetector comprises at least one sensor configured for generating an analog sensor charge dependent on an illumination of a light-sensitive region of the sensor. The photodetector comprises at least one readout-circuit according to any one of the embodiments disclosed above or below in further detail. For further details and embodiments of the photodetector, reference may be made to the description of the readout-circuit above.

In a further aspect of the present invention, a method for readout of an analog sensor charge is disclosed. The method comprises:
a) providing at least one readout-circuit according to any one of the embodiments disclosed above or below in further detail referring to a readout-circuit;
b) converting the analog sensor charge into a first digital output count and an analog voltage remainder by using the IAF-circuit; and
c) converting the analog voltage remainder into a second digital output by using the ADC.

The method may further comprise:
d) determining a combined digital output count by combining the first digital output count and the second digital output.

The method may comprise further method steps which are not listed. Further, one or more of the method steps may be performed once or repeatedly. Further, two or more of the method steps may be performed simultaneously or in a timely overlapping fashion.

The term “providing”, including any grammatical variation thereof, as used herein is a broad term and is to be given its ordinary and customary meaning to a person of ordinary skill in the art and is not to be limited to a special or customized meaning. The term specifically may refer, without limitation, to at least one of manufacturing a readout-circuit, producing a readout-circuit, using an existing readout-circuit, applying an existing readout-circuit and modifying an existing readout-circuit.

The readout may comprise a readout of at least one sensor of at least one photodetector according to any of the embodiments disclosed above or below in further detail referring to a photodetector. A resolution of the readout may be controlled by varying a resolution of the second digital output in step c). The term “resolution” as used herein is a broad term and is to be given its ordinary and customary meaning to a person of ordinary skill in the art and is not to be limited to a special or customized meaning. The term specifically may refer, without limitation, to an indication of how finely graduated an originally analog signal such as the analog sensor charge or a light intensity impinging the photodetector can be digitized. Specifically, the resolution may indicate how finely graduated the analog signal can be digitized. Thus, the higher the resolution, the finer the steps in a digitized signal may be. An “N”-bit ADC may increase the resolution of the readout-circuit by “N” bits. Thus, the resolution of the readout-circuit may comprise a whole number of saturation events and a decimal number relating to a final unfinished integration cycle. The whole number of the saturation events may be captured by using the IAF-circuit. The decimal number relating to a final unfinished integration cycle may be captured by using the ADC. The IAF-circuit may be less sensitive to current input or charge input, specifically compared to the ADC. As an example, for sufficiently high currents, bits from the ADC may be decreased for adjusting resolution. Additionally or alternatively, a gain, specifically a charge-to-voltage gain, of the readout may be controlled by varying a resolution of the second digital output in step c). The gain may be controlled by utilizing more or less of the bits from the analog voltage remainder.

In a further aspect of the present invention, a use of a readout-circuit according to the present invention is disclosed for a purpose of readout of one or more of at least one PbS sensor, at least one PbSe sensor, or at least one pixelated sensor array comprising a plurality of pixels, wherein each of the pixels comprises at least one PbS or PbSe sensor. In particular, the readout-circuit according to the present invention may be used in modest or low bias voltage applications, for example in applications where devices are battery operated or need to run on low power e.g. sensor nodes, portable measurement devices, devices in explosive atmospheres, allowing an improved signal-to-noise ratio and thus high signal quality. For example, the readout-circuit may be used in spectrometers, moisture measurement instruments, thickness measurement instruments, gas analysis instruments or any other type of equipment using photoconductors as sensor element. The readout-circuit may be used in optical sensors. For example, the readout-circuit may be used in optical sensors which employ the so-called FiP effect, for example WO 2012/110924 A1, WO 2014/097181 A1 and WO 2016/120392 A1.

In a further aspect of the present invention, a non-transient computer-readable medium is disclosed. The non-transient computer-readable medium includes instructions that, when executed by one or more processors, cause the one or more processors to perform the method according to any one of the embodiments disclosed above or below in further detail referring to a method.

Further disclosed and proposed herein is a computer program including computer-executable instructions for performing the method according to the present invention in one or more of the embodiments enclosed herein when the program is executed on a computer or computer network. Specifically, the computer program may be stored on a computer-readable data carrier and/or on a computer-readable storage medium.

As used herein, the terms “computer-readable data carrier” and “computer-readable storage medium” specifically may refer to non-transitory data storage means, such as a hardware storage medium having stored thereon computer-executable instructions. The computer-readable data carrier or storage medium specifically may be or may comprise a storage medium such as a random-access memory (RAM) and/or a read-only memory (ROM).

Thus, specifically, one, more than one or even all of method steps as indicated above may be performed by using a computer or a computer network, preferably by using a computer program.

Further disclosed and proposed herein is a computer program product having program code means, in order to perform the method according to the present invention in one or more of the embodiments enclosed herein when the program is executed on a computer or computer network.

Specifically, the program code means may be stored on a computer-readable data carrier and/or on a computer-readable storage medium.

Further disclosed and proposed herein is a data carrier having a data structure stored thereon, which, after loading into a computer or computer network, such as into a working memory or main memory of the computer or computer network, may execute the method according to one or more of the embodiments disclosed herein.

Further disclosed and proposed herein is a computer program product with program code means stored on a machine-readable carrier, in order to perform the method according to one or more of the embodiments disclosed herein, when the program is executed on a computer or computer network. As used herein, a computer program product refers to the program as a tradable product. The product may generally exist in an arbitrary format, such as in a paper format, or on a computer-readable data carrier and/or on a computer-readable storage medium. Specifically, the computer program product may be distributed over a data network.

Finally, disclosed and proposed herein is a modulated data signal which contains instructions readable by a computer system or computer network, for performing the method according to one or more of the embodiments disclosed herein.

Referring to the computer-implemented aspects of the invention, one or more of the method steps or even all of the method steps of the method according to one or more of the embodiments disclosed herein may be performed by using a computer or computer network. Thus, generally, any of the method steps including provision and/or manipulation of data may be performed by using a computer or computer network. Generally, these method steps may include any of the method steps, typically except for method steps requiring manual work, such as providing the samples and/or certain aspects of performing the actual measurements.

Specifically, further disclosed herein are:
a computer or computer network comprising at least one processor, wherein the processor is adapted to perform the method according to one of the embodiments described in this description,
a computer loadable data structure that is adapted to perform the method according to one of the embodiments described in this description while the data structure is being executed on a computer,
a computer program, wherein the computer program is adapted to perform the method according to one of the embodiments described in this description while the program is being executed on a computer,
a computer program comprising program means for performing the method according to one of the embodiments described in this description while the computer program is being executed on a computer or on a computer network,
a computer program comprising program means according to the preceding embodiment, wherein the program means are stored on a storage medium readable to a computer,
a storage medium, wherein a data structure is stored on the storage medium and wherein the data structure is adapted to perform the method according to one of the embodiments described in this description after having been loaded into a main and/or working storage of a computer or of a computer network, and
a computer program product having program code means, wherein the program code means can be stored or are stored on a storage medium, for performing the method according to one of the embodiments described in this description, if the program code means are executed on a computer or on a computer network.

The devices and methods according to the present invention may provide a large number of advantages over known devices and methods. Specifically, they may be suited for reducing size, complexity, cost, power consumption and noise of readout-circuits, specifically for photodetectors, while still ensuring a reliable and accurate readout, specifically also of small analog sensor charges. They may further allow for achieving a wider dynamic range and more flexibility in selecting a charge-to-voltage gain. As an example, a 16-bit resolution may be achievable over a wider charge range.

As used herein, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may both refer to a situation in which, besides B, no other element is present in A (i.e. a situation in which A solely and exclusively consists of B) and to a situation in which, besides B, one or more further elements are present in entity A, such as element C, elements C and D or even further elements.

Further, it shall be noted that the terms “at least one”, “one or more” or similar expressions indicating that a feature or element may be present once or more than once typically are used only once when introducing the respective feature or element. In most cases, when referring to the respective feature or element, the expressions “at least one” or “one or more” are not repeated, notwithstanding the fact that the respective feature or element may be present once or more than once.

Further, as used herein, the terms “preferably”, “more preferably”, “particularly”, “more particularly”, “specifically”, “more specifically” or similar terms are used in conjunction with optional features, without restricting alternative possibilities. Thus, features introduced by these terms are optional features and are not intended to restrict the scope of the claims in any way. The invention may, as the skilled person will recognize, be performed by using alternative features. Similarly, features introduced by “in an embodiment of the invention” or similar expressions are intended to be optional features, without any restriction regarding alternative embodiments of the invention, without any restrictions regarding the scope of the invention and without any restriction regarding the possibility of combining the features introduced in such way with other optional or non-optional features of the invention.

Summarizing and without excluding further possible embodiments, the following embodiments may be envisaged:
Embodiment 1: A readout-circuit configured for converting an analog sensor charge into a digital output count, wherein the readout-circuit comprises at least one integrate-and-fire(IAF)-circuit, wherein the IAF-circuit is configured for converting the analog sensor charge into a first digital output count, wherein the readout-circuit is further configured for processing an analog voltage remainder after a final IAF cycle, wherein the readout-circuit comprises at least one analog-to-digital-converter (ADC), wherein the ADC is configured for converting the analog voltage remainder into a second digital output.
Embodiment 2: The readout-circuit according to the preceding embodiment, wherein the readout-circuit is configured for readout of a small analog sensor charge, specifically an analog sensor charge of less than 1nC, more specifically of less than 1pC.
Embodiment 3: The readout-circuit according to any one of the preceding embodiments, wherein the readout-circuit is configured for readout of at least one sensor configured for generating the analog sensor charge dependent on an illumination of a light-sensitive region of the sensor.
Embodiment 4: The readout-circuit according to the preceding embodiment, wherein the readout-circuit is configured for readout of a plurality of sensors configured for generating the analog sensor charge dependent on an illumination of a light-sensitive region of the sensor, wherein the sensors are arranged in an array.
Embodiment 5: The readout-circuit according to any one of the two preceding embodiments, wherein the light-sensitive region comprises at least one photoconductive material selected from the group consisting of lead sulfide (PbS); lead selenide (PbSe); mercury cadmium telluride (HgCdTe); cadmium sulfide (CdS); cadmium selenide (CdSe); indium antimonide (InSb); indium arsenide (InAs); indium gallium arsenide (InGaAs); silicon (Si); Silicon Germanium (SiGe); extrinsic semiconductors, organic semiconductors.
Embodiment 6: The readout-circuit according to any one of the preceding embodiments, wherein the readout-circuit is configured for determining a combined digital output count by combining the first digital output count and the second digital output, wherein the first digital output count (118) is proportional to a whole number of integration cycles, wherein the second digital output (124) is proportional to a remainder voltage of a final uncompleted integration cycle.
Embodiment 7: The readout-circuit according to any one of the preceding embodiments, wherein the IAF-circuit is configured for digitizing the analog sensor charge at least up to the analog voltage remainder, wherein the analog voltage remainder is a for the IAF-circuit non-digitizable remainder.
Embodiment 8: The readout-circuit according to any one of the preceding embodiments, wherein the IAF-circuit comprises
   at least one integrator, wherein the integrator comprises at least one operational amplifier and at least one capacitor, wherein an input of the operational amplifier is held to a known voltage V_{ref}, wherein the integrator is configured for resetting an output of the operational amplifier is reset to V_{ref} after each saturation event, wherein the integrator is configured for integrating the output of the operational amplifier between the reference voltage V_{ref} and a comparator voltage V_{comp} for determining an integration voltage Vᵢₙₜ;
   at least one comparator, specifically at least one Schmitt-trigger, configured for determining a saturation event;
   at least one counter configured for determining the first digital output count by counting the saturation events; and
   at least one mixed signal circuit configured for resetting Vᵢₙₜ to V_{ref} after each saturation event
Embodiment 9: The readout-circuit according to the preceding embodiment, wherein the analog voltage remainder is a leftover voltage after a final IAF cycle that has not triggered a saturation event.
Embodiment 10: The readout-circuit according to any one of the preceding embodiments, wherein the ADC comprises at least one ADC architecture selected from the group consisting of a counter type ADC, a single-slope ADC, a dual-slope ADC, a pipelined ADC, a successive-approximation (SAR) ADC, a sigma-delta ADCs.
Embodiment 11: The readout-circuit according to any one of the preceding embodiments, wherein the ADC comprises a counter type ADC, wherein the ADC and the IAF-circuit share at least one component, specifically at least one comparator.
Embodiment 12: The readout-circuit according to any one of the preceding embodiments, wherein the ADC has a low resolution, specifically 14-bit or less, more specifically 10-bit or less.
Embodiment 13: A photodetector comprising
   at least one sensor configured for generating an analog sensor charge dependent on an illumination of a light-sensitive region of the sensor; and
   at least one readout-circuit according to any one of the preceding embodiments.
Embodiment 14: The photodetector according to the preceding embodiment, wherein the photodetector comprises a plurality of sensors, wherein the sensors are arranged in an array.
Embodiment 15: The photodetector according to any one of the preceding embodiments referring to a photodetector, wherein the light-sensitive region comprises at least one photoconductive material selected from the group consisting of lead sulfide (PbS); lead selenide (PbSe); mercury cadmium telluride (HgCdTe); cadmium sulfide (CdS); cadmium selenide (CdSe); indium antimonide (InSb); indium arsenide (InAs); indium gallium arsenide (InGaAs); silicon (Si); Silicon Germanium (SiGe); extrinsic semiconductors, organic semiconductors.
Embodiment 16: A method for readout of an analog sensor charge, the method comprising:
   a) providing at least one readout-circuit according to any one of the preceding embodiments referring to a readout-circuit;
   b) converting the analog sensor charge into a first digital output count and an analog voltage remainder by using the IAF-circuit; and
   c) converting the analog voltage remainder into a second digital output by using the ADC.
Embodiment 17: The method according to the preceding embodiment, further comprising:
   d) determining a combined digital output count by combining the first digital output count and the second digital output.
Embodiment 18: The method according to any one of the preceding method embodiments, wherein the readout comprises a readout of at least one sensor of at least one photodetector according to any of the preceding embodiments referring to a photodetector.
Embodiment 19: The method according to any one of the preceding method embodiments, wherein a resolution of the readout is controlled by varying a resolution of the second digital output in step c).
Embodiment 20: The method according to any one of the preceding method embodiments, wherein a gain, specifically a charge-to-voltage gain, of the readout is controlled by varying a resolution of the second digital count in step c).
Embodiment 21: A non-transient computer-readable medium including instructions that, when executed by one or more processors, cause the one or more processors to perform the method according to any one of the preceding embodiments referring to a method.
Embodiment 22: A use of a readout-circuit according to any one of the preceding embodiments referring to a readout-circuit for readout of one or more of at least one PbS sensor, at least one PbSe sensor, or at least one pixelated sensor array comprising a plurality of pixels, wherein each of the pixels comprises at least one PbS or PbSe sensor.

### SHORT DESCRIPTION OF THE FIGURES

Further optional features and embodiments will be disclosed in more detail in the subsequent description of embodiments, preferably in conjunction with the dependent claims. Therein, the respective optional features may be realized in an isolated fashion as well as in any arbitrary feasible combination, as the skilled person will realize. The scope of the invention is not restricted by the preferred embodiments. The embodiments are schematically depicted in the Figures. Therein, identical reference numbers in these Figures refer to identical or functionally comparable elements.

In the Figures:

FIG. 1 shows an exemplary embodiment of a schematic circuit diagram of a readout-circuit;

FIGS. 2A-2B show a further exemplary embodiment of a schematic circuit diagram of a readout-circuit and a corresponding voltage diagram;

FIGS. 3A-3B show experimental results of measurements on an exemplary embodiment of a readout-circuit;

FIG. 4 shows an exemplary embodiment of a photodetector; and

FIG. 5 shows a flow chart of an exemplary embodiment of a method for readout of an analog sensor charge.

### DETAILED DESCRIPTION OF THE EMBODIMENTS

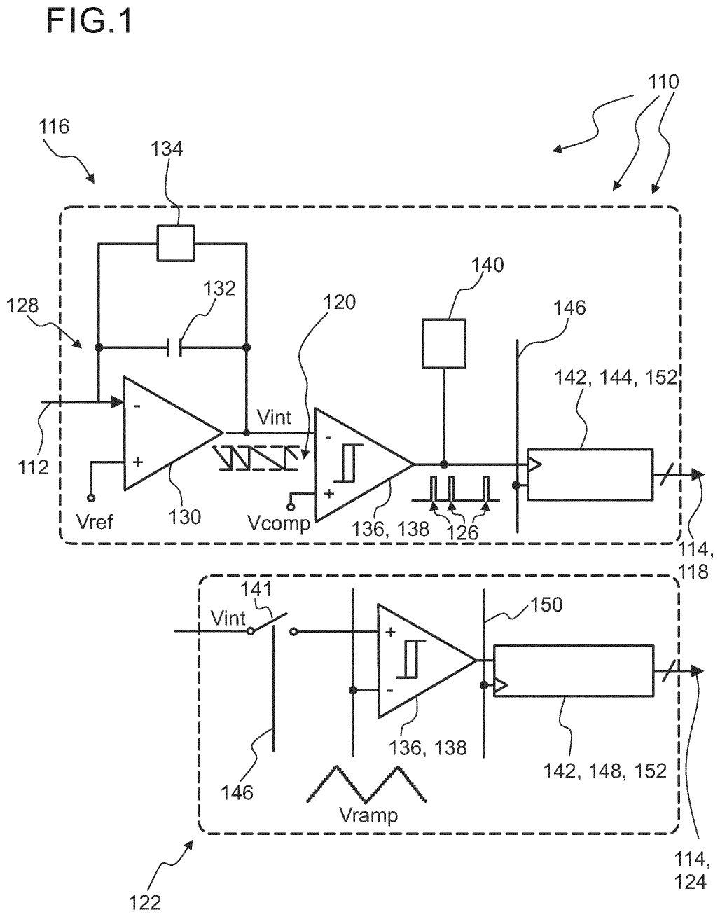

FIG. 1 shows an exemplary embodiment of a schematic circuit diagram of a readout-circuit 110. The readout-circuit 110 is configured for converting an analog sensor charge 112 into a digital output count 114. The readout-circuit 110 comprises at least one integrate-and-fire(IAF)-circuit 116. The IAF-circuit 116 is configured for converting the analog sensor charge into a first digital output count 118. The readout-circuit 110 is further configured for processing an analog voltage remainder 120 after a final IAF cycle. The readout-circuit 110 comprises at least one analog-todigital-converter (ADC) 122. The ADC 122 is configured for converting the analog voltage remainder into a second digital output 124. The readout-circuit 110 may be an electric circuit configured for quantifying and/or processing at least one physical property and/or a change in at least one physical property detected by at least one measurement device.

As indicated in FIG. 1, the IAF-circuit 116 and the ADC 122 may be separate entities. However, as will also be outlined in further detail below, the IAF-circuit 116 and the ADC 122 may also at least partially share components. At least, the IAF-circuit 116 and the ADC 122 may be connected to each other or, more specifically, components of them may be connected to each other. The ADC 122 may be an extension to the IAF-circuit 116. In the following, the components of the IAF-circuit 116 and the ADC 122 will be described in view of FIG. 1.

The IAF-circuit 116 may be an electric circuit configured for integrating the incoming analog sensor charge 112 and firing an event 126, when an output voltage reaches a predefined quantization threshold. The event 126 can be used to reset the integrator 128 in order to start again with the integration of the incoming analog sensor charge 112. Different types of IAF-circuits are generally known to the skilled person, e.g. from the publication Dei, Michele, et al. “Highly linear integrate-and-fire modulators with soft reset for low-power high-speed imagers.” 2017 IEEE International Symposium on Circuits and Systems (ISCAS). IEEE, 2017, which is included here in its entirety. The IAF-circuit 116 may comprise at least one integrator 128. The integrator 128 may be an electric circuit configured for integrating at least one input signal, specifically over time. The integrator 128 may be configured for accumulating the input signal over time. Specifically, the integrator 128 may be a current integrator 128. The integrator 128 may be configured for measuring the analog sensor charge 112. The integrator 128 may comprise at least one of an operational amplifier 130 and a capacitor 132. The operational amplifier 130 may be an inverted operational amplifier 130. The operational amplifier 130 and the capacitor 132 may be connected in parallel. The IAF-circuit 116 may specifically comprise the at least one capacitor 132, wherein the IAF-circuit 116 may be configured for employing a linear nature of a charge-to-voltage conversion using the capacitor 132. The integrator 128 may comprise at least one mixed signal circuit 134, specifically for resetting the integrator 128. Thus, the IAF-circuit 116 may comprise at least one mixed signal circuit 134 configured for resetting Vᵢₙₜ after each saturation event 126. The mixed signal circuit 134 may be connected in parallel to the integrator 128 or the capacitor 132 of the integrator 128 generating a short circuit when closed. The mixed signal circuit 134 may be an electrical switch or an electromechanical switch. The mixed signal circuit 134 may comprise at least one transistor such as a field effect transistor or a bipolar junction transistor. Specifically, the mixed signal circuit 134 may comprise at least one transmission gate. The reset of the output of the operational amplifier 130 may be a critical component of the IAF-circuit 116. The IAF-circuit 116 may be configured to ensure that the reset happens quickly and automatically after each saturation event 126. The analog voltage needs to be consistently returned to V_{ref} after every event 126.

An input of the operational amplifier 130 may be held to a known voltage V_{ref}. The integrator may 128 be configured for resetting an output of the operational amplifier 130 to V_{ref} after each saturation event 126. The integrator 128 may be configured for integrating the output of the operational amplifier 130 between the reference voltage V_{ref} and a comparator voltage V_{comp} for determining an integration voltage Vᵢₙₜ. The output of the operational amplifier 130 Vᵢₙₜ may be thus V_{ref}≥Vᵢₙₜ≥V_{comp}.

The IAF-circuit 116 may further comprise at least one comparator 136 configured for determining a saturation event 126 when Vᵢₙₜ reaches V_{comp}. The comparator 136 may be configured for firing the event 126. The comparator 136 may be an electric circuit configured for comparing at least two input signals, specifically voltages, such as Vᵢₙₜ and V_{comp}. The comparator 136 may be configured for generating at least one output signal, specifically a digital output signal, indicating a result of the comparison, e.g. which input signal is larger. As an example, the comparator 136 may generate as an output “HIGH” or “1” in the case that a first input voltage is higher than a second input voltage and “LOW” or “0” in the case that the first input voltage is lower than the second input voltage. The output signal may be generated continuously over time, specifically for varying input signals. The comparator 136 may be configured for comparing Vᵢₙₜ with V_{comp}. Specifically, the comparator 136 may be configured for detecting when Vᵢₙₜ is equal to V_{comp}. The comparator 136 may be configured for generating an event signal, also denoted as event, each time Vᵢₙₜ crosses V_{comp}.

The comparator 136 may be and/or may comprise at least one Schmitt-trigger 138. The Schmitt-trigger 138 may be an inverting or a non-inverting Schmitt-trigger 138. The Schmitt-trigger 138 may be a comparator circuit in which switch-on and switch-off thresholds are offset from each other by a switching hysteresis. The Schmitt-trigger 138 may be configured for comparing an input voltage, specifically a voltage varying over time, with two threshold voltages, an upper threshold voltage and a lower threshold voltage. Specifically, the Schmitt-trigger 138 may be configured for giving out HIGH or 1 in case the input voltage is higher than the upper threshold voltage and LOW or 0 in case the input voltages is lower than the lower threshold voltage, wherein the Schmitt-trigger 138 may further be configured for maintaining a preceding output between the upper threshold voltage and the lower threshold voltage. As long as the input voltage does not exceed one of the two threshold voltage, an output of the Schmitt-trigger 138 may not be altered. However, other options for a comparator 136 are also feasible. The comparator 136 may be connected to an output of the integrator 128, specifically to an output of the operational amplifier 130 of the integrator 128. The comparator 136, specifically an output of the comparator 136, may further be connected to at least one switch control 140. The switch control 140 may be configured for controlling the mixed signal circuit 134 for resetting the integrator 128. The readout-circuit 110, specifically the ADC 122, may comprise at least one switch 141. The switch control 140 may be configured for controlling the switch 141.

The IAF-circuit 116 may further comprise at least one counter 142 configured for determining the first digital output count 118 by counting the saturation events 126. The counter 142 may be an electric circuit configured for counting the events 126. The counter 142 may be configured for storing a number of times a particular event 126 has occurred. Specifically, for each determined saturation event 126, the counter 142 may be incremented by 1. The counter 142 may comprise at least one output. The counter 142 may be configured for giving out the count. The counter 142 may be configured for giving out the number of times a particular event 126 has occurred, specifically in a binary number system. The counter 142 may comprise a plurality of flip-flops connected in a cascade. The counter 142 may be a synchronous counter or an asynchronous counter 142. The counter 142 may comprise at least one input. An input of the counter 142 may be connected to the above-described comparator 136. The readout-circuit 110 may comprise a plurality of counters 142. Specifically, the counter 142 of the IAF-circuit 116 may be a MSB counter 144. The MSB counter 144 may be configured for determining the most significant bits (MSB) of an output of the readout-circuit 110. The MSB counter 144 may be configured for determining the first digital output count 118. A further input of the MSB counter 144 may be connected to a shutter 146, specifically to a global shutter 146, such as a global shutter 146 shared with the ADC 122 of the readout-circuit 110. The global shutter 146 may be configured for transferring at least one signal, specifically a voltage, from the IAF-circuit 116 to the ADC 122.

The ADC 122 may be an electric circuit configured for converting or transferring at least one analog input signal, specifically the analog sensor charge 112, into at least one digital output signal, specifically the digital output count 114. For example, the ADC 122 may be a counter type ADC 122. However, in principle, any known ADC architecture may be used for the ADC 122 for converting the analog voltage remainder into a second digital output. For example, the ADC may comprise at least one ADC architecture selected from the group consisting of a counter type ADC, a single-slope ADC, a dual-slope ADC, a pipelined ADC, a successive-approximation (SAR) ADC, a sigma-delta ADCs. With respect to embodiments of the ADC 122 reference is made to “Analog-to-Digital Converter Architectures and Choices for System Design” by Brian Black, Analog Dialogue 33-8 (1999). The ADC 122 may have a low resolution, specifically 14-bit or less, more specifically 10-bit or less. Using a simple ADC requiring only little power supply and only little area may be possible. The ADC 122 may specifically comprise at least one of a comparator 136, specifically a Schmitt-trigger 138, and a counter 142. A V+ terminal of the comparator 136 may be ramped via a digital-to-analog-converter (DAC) from V_{comp} to Vᵢₙₜ in 2^{N} steps. During ramping, the V_{comp} voltage may cross the Vᵢₙₜ remainder voltage and the comparator output may be triggered. At this point, a counter 142 may be activated and every remaining V+ step from the DAC increments the counter. The final count on the counter 142 may be a digitized representation of the voltage remainder Vᵢₙₜ. The readout-circuit 110 may comprise at least one switch 141 for resetting the counter 142. For example, the counter 142 may comprise a reset pin to reset the count back to 0. Using a counter type ADC may allow sharing the comparator circuitry.

As already indicated, in principle, the ADC 122 and the IAF-circuit 116 may share at least one component, specifically at least one comparator 136. Specifically, the ADC 122 and the IAF-circuit 116 may share the Schmitt-trigger 138. For example, the Schmitt-trigger 138 connected to the integrator 128 of the IAF-circuit 116 may also be used as part of the ADC 122. However, as said and as indicated in FIG. 1, the ADC 122 and the IAF-circuit 116 may also be separate entities, which may be connected to each other, specifically by using the shutter 146. Specifically, the ADC 122 may be an extension to the IAF-circuit 116. An input of the comparator 136 of the ADC 122, may be connected to an output of the comparator 136 of the IAF-circuit 116 by using the shutter 146. A further input of the comparator 136 of the ADC 122 may be connected to ramp voltage Vᵣₐₘₚ, such that an integration voltage Vᵢₙₜ transferred from the IAF-circuit 116 may be compared to Vᵣₐₘₚ in the ADC 122.

As said, the ADC 122 may further comprise the at least one counter 142. An input of the counter 142 of the ADC 122 may be connected to the output of the Schmitt-trigger 138 of the ADC 122. The counter 142 of the ADC 122 may be a LSB counter 148. The LSB counter 148 may be configured for determining the least significant bits (LSB) of an output of the readout-circuit 110. As indicated, an input of the LSB counter 148 may be connected to an output of the comparator 136 of the ADC 122. A further input of the LSB counter 148 may specifically be connected to a clock 150, specifically a global clock 150 of the readout-circuit 110. The LSB counter 148 may be a synchronous counter 142 triggered by the clock 150. The LSB counter 148 may be configured for determining the second digital output 124. The second digital output 124 may be an arbitrary digital output generated by the ADC 122 proportional to the remainder voltage of the final uncompleted integration cycle. For example, the second digital output 124 may be a digital output count. However, other options are feasible. The second digital output 124 may be proportional to the remainder voltage of the final but uncompleted integration cycle. The ADC 122 may be a counter 142 of least significant bits (LSB), such as the LSB counter 148. The LSB counter 148 may be configured for determining the least significant bits of an output of the readout-circuit 110.

The readout-circuit 110 may be configured for determining a combined digital output count 114 by combining the first digital output count 118 and the second digital output 124. The combined digital output count 114 may be given out in the binary number system. As described, the IAF-circuit 116 may be configured for determining the most significant bits (MSB) and the ADC 122 may be configured for determining the least significant bits (LSB). The M-bits of the MSB counter 144 may represent the number of completed integration cycles and the N-bits of the LSB counter 148 may represent the binary completed value of the remainder voltage on the IAF. The combined digital value of MSB concatenated with LSB may represent a N+M bit digital resolution. The readout-circuit 110 may comprise at least one output unit 152 and/or at least one interface such as to at least one further device, e.g. for further evaluation. The output unit 152 may be configured for generating at least one output, specifically at least one digital output voltage signal, such as the combined digital output count 114. The output unit 152 may be configured for passing the output to at least one external device or element, e.g. to a processor for further evaluation. As an example, the output unit 152 may be configured for identifying or marking the most significant bits and/or the least significant bits, such that e.g. a processor can assign them correctly. The MSB counter 144 and/or the LSB counter 148 may at least partially form the output unit 152. A processor receiving the first digital output count 118 from the MSB counter 144 and the second digital output 124 from the LSB counter 148 may be configured for using the first digital output count 118 from the MSB counter 144 as most significant bits and the second digital output 124 from the LSB counter 148 as least significant bits for a combined digital output count 114.

In the following, the operation of the readout-circuit 110 will be described in view of FIG. 1. At first, the analog sensor charge 112 may arrive at the the IAF-circuit 116, specifically at the integrator 128 of the IAF-circuit 116. The integrator 128 may determine an integration voltage Vᵢₙₜ by integrating the analog sensor charge 112 between a reference voltage V_{ref} and a comparator voltage V_{comp}. The integration voltage Vᵢₙₜ may be a voltage output generated by the integrator 128, specifically by the operational amplifier 130. The reference voltage V_{ref} may be a predefined voltage serving as a reference, specifically for the integrator 128. The reference voltage may specifically be applied to the operational amplifier 130, specifically to a first input of the typically two inputs of the operational amplifier 130. The analog sensor charge 112 may specifically be fed into a second input of the operational amplifier 130. An output of the operational amplifier 130 may further be fed back into the second input, specifically via the capacitor 132. Due to charge integration and resetting, the integration voltage Vᵢₙₜ may be a triangular signal over time as indicated in FIG. 1. With analog sensor charge 112 being directed to the integrator 128, the generated integration voltage Vᵢₙₜ may increase over time until the integrator 128 is reset by using the mixed signal circuit 134 of the integrator 128. Such a process of the integration voltage Vᵢₙₜ being built up and being reset may be referred to as a finished integration cycle. As already mentioned, a finished integration cycle may refer to a for the IAF-circuit 116 countable saturation event 126. However, if the integration voltage Vᵢₙₜ being present is not large enough for triggering a saturation event 126, such as in a final unfinished integration cycle, the integration voltage Vᵢₙₜ may remain as an analog voltage remainder 120 without being reset. Thus, as an example and as indicated in FIG. 1, the integration voltage Vᵢₙₜ remaining at the output of the operational amplifier 130 at the final unfinished integration cycle may be the analog voltage remainder 120.

The saturation event 126 may be an occurrence of a saturation or a satiation of an electric component, specifically of the integrator 128, more specifically of the capacitor 132 of the integrator 128. The saturation event 126 may refer to an event of maximum charge on the capacitor 132. The saturation may depend on at least one geometric property, specifically on a size, of the capacitor 132. The smaller the capacitor 132, the faster a saturation may occur and the more saturation events 126 may occur over time. A capacitance of the capacitor 132 may be defined by the size of the capacitor 132, e.g. by a ratio of an area of capacitor plates divided by a distance between the capacitor plates. The occurrence of a saturation event 126 may refer to a finished integration cycle of the integrator 128. As outlined above, in case the saturation event 126 occurs, the integration voltage Vᵢₙₜ may reach the predefined quantization threshold V_{comp} and the comparator 136 of the IAF-circuit 116 may fire an event signal which can be counted. Specifically, the IAF-circuit 116 may be configured for converting the analog sensor charge 112 into the first digital output count 118 by counting the integration cycles. Each finished integration cycle may increment the first digital output count 118.

The saturation event 126 may be determined by using the comparator 136 of the IAF-circuit 116 and the comparator voltage V_{comp}. Vᵢₙₜ may be fed into a first input of the typically two inputs of the comparator 136 of the IAF-circuit 116. V_{comp} may be fed into a second input of the typically two inputs of the comparator 136 of the IAF-circuit 116. V_{comp} may be a predefined voltage serving as a reference or threshold, specifically for the comparator 136 of the IAF-circuit 116. The comparator 136 of the IAF-circuit 116 may be configured for comparing Vᵢₙₜ with V_{comp}. Specifically, the comparator 136 of the IAF-circuit 116 may be configured for detecting when Vᵢₙₜ is equal to V_{comp}. This condition may be indicative of a saturation event 126, specifically for V_{comp} being selected accordingly. In case a saturation event 126 is detected, the comparator 136 may fire an event signal which can be counted, specifically by the MSB counter 144. The comparator 136 may be configured for determining a saturation event 126 when Vᵢₙₜ reaches V_{comp} and for firing an event signal. However, at the final integration cycle, also denoted as final IAF cycle, of integrating the incoming analog sensor charge 112, there may be a remainder which, because the integrated voltage does not reach the quantization threshold V_{comp} (Vᵢₙₜ<V_{comp}), cannot trigger firing an event and, thus, is not counted. The analog voltage remainder 120 may be a remainder or a rest or a residual which is left after a complete processing of the analog sensor charge 112 by the IAF-circuit 116, specifically at the end of the final finished integration cycle. The remainder may be one or more of characterized, described or quantified by using at least one analog voltage. The analog voltage remainder 120 may refer to a remainder of a final unfinished integration cycle. The IAF-circuit 116 may be configured for digitizing the analog sensor charge 112 at least up to the analog voltage remainder 120.

An event signal fired by the comparator 136 of the IAF-circuit 116 may be directed to the MSB counter 144. The MSB counter 144 may be configured for counting the saturation events 126 and for incrementing the first digital output count 118 accordingly. An event signal fired by the comparator 136 of the IAF-circuit 116 may further be directed to the switch control 140 for resetting the integrator 128. An analog voltage remainder 120 may be directed to the ADC 122 by using the shutter 146 and/or the switch 141 of the ADC 122. At the comparator 136 of the ADC 122, Vᵢₙₜ may be compared to a ramp voltage Vᵣₐₘₚ. Vᵣₐₘₚ may increase and/or decrease. When Vᵣₐₘₚ reaches Vᵢₙₜ, a signal may be passed on the LSB counter 148. The LSB counter 148 may subsequently start counting by using the clock 150 for generating the second digital output 124. Specifically, when the integration at the IAF-circuit 116 completes, there may exist an analog voltage remainder Vᵢₙₜ at the output of the operational amplifier 130 such that V_{ref}≥Vᵢₙₜ>V_{comp}. The IAF-circuit 116 may trigger automatically an IAF reset in case Vᵢₙₜ crosses V_{comp}. The remainder voltage may be the leftover voltage that has not triggered an IAF reset. The analog voltage remainder 120 may be quantized by the ADC 122 to yield a value representing the binary percent completion of the operational amplifier 130 output voltage. A binary value of 0 would represent the voltage Vᵢₙₜ and the binary value 2^{N}−1 would represent the value V_{comp}, where N is the number of bits of resolution for the ADC 122. ADC values between 0 and 2^{N}−1 may represent the analog voltage remainder 120.

The first digital output count 118 and the second digital output 124 may then be passed on, e.g. to a processor for further evaluation of the analog sensor charge 112. The readout-circuit 110 may be configured for readout of a small analog sensor charge 112, specifically an analog sensor charge 112 of less than 1nC, more specifically of less than 1pC. As explained, specifically by using the ADC 122 for determining the least significant bits, also a small analog sensor charge 112 may be digitized which does not trigger a saturation event 126 at the integrator 128 of the IAF-circuit 116.

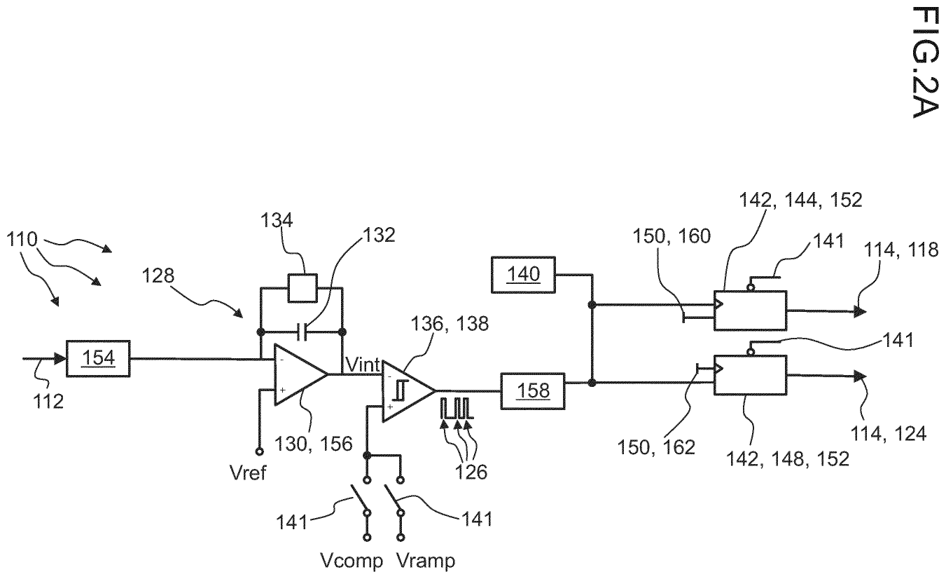

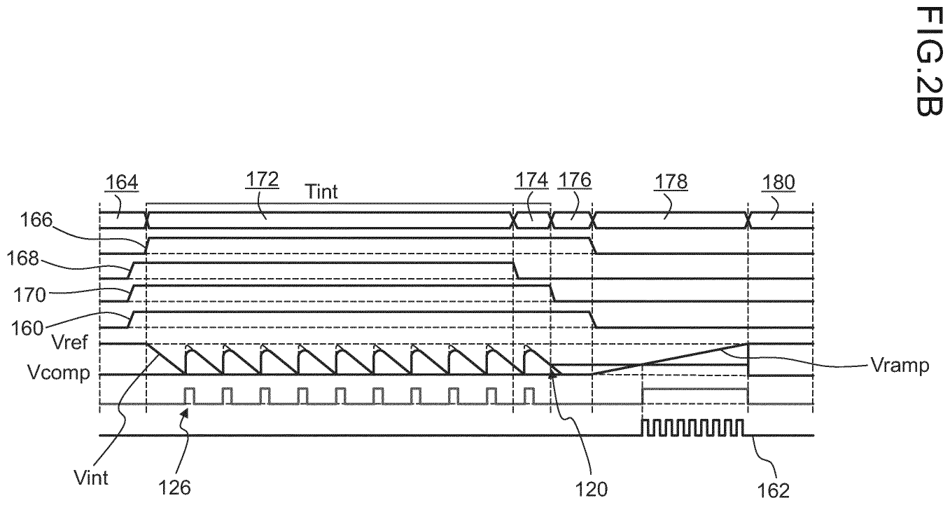

FIGS. 2A-2B show a further exemplary embodiment of a schematic circuit diagram of a readout-circuit 110 and a corresponding voltage signal-state diagram. For the description of FIG. 2A, it can largely be referred to the description of FIG. 1 above. FIG. 2A shows an exemplary embodiment of the readout-circuit 110, in which the IAF-circuit 116 and the ADC 122 may share the comparator 136. Thus, there may be no more clear separation between the IAF-circuit 116 and the ADC 122 in the readout-circuit 110, but both may be integrated in one common electric circuit. The analog sensor charge 112 may be directed to at least one transmission gate 154. The transmission gate 154 may be configured for directing the analog sensor charge 112 to at least one of the integrator 128 and a dummy integrator. Thus, from the transmission gate 154, the analog sensor charge 112 may be directed to the integrator 128. The integrator 128 may comprise the operational amplifier 130, which may specifically be a capacitive trans-impedance amplifier 156, and the capacitor 132. The integrator 128 may generate an integration voltage Vᵢₙₜ. The integration voltage Vᵢₙₜ may be directed to the comparator 136, which may specifically be the Schmitt-trigger 138. The comparator 136 may generate an event signal each time Vᵢₙₜ crosses V_{comp}. The readout-circuit 110 may comprise at least one event handler 158. The event handler 158 may be configured for identifying the comparator events 126. The event handler 158, based on the comparator events 126, may then initiate a reset of the integrator 128, such as by using the switch control 140. Additionally or alternatively, the event handler 158 may initiate at least one of the counters 142. Additionally or alternatively, the event handler 158 may initiate digitizing the analog voltage remainder 120, such as by configuring the comparator 136 for digitizing the analog voltage remainder 120. The event handler 158 may set an appropriate counter input based on a comparator output clocked via the system clock 150. The MSB counter 144 and/or the LSB counter 148 may be connected to at least one clock 150. The MSB counter 144 may be connected to an integrate-and-fire clock (IAF clock) 160. The LSB counter 148 may be connected to an analog-to-digital-converter clock (ADC clock) 162.

The event handler 158 may further be connected to the switch control 140. The switch control 140 may be configured for controlling at least one switch 141 of the readout-circuit 110. Specifically, the switch control 140 may be configured for controlling the mixed signal circuit 134 of the readout-circuit 110. The readout-circuit 110 may comprise at least one mixed signal circuit 134 for resetting the integrator 128. The readout-circuit 110 may comprise at least one switch 141 configured for resetting at least one of the MSB counter 144 and the LSB counter 148, such as for initializing a new readout. The readout-circuit 110 may comprise at least one switch 141 for selectively assigning at least one voltage to at least one component of the readout-circuit 110. The readout-circuit 110 may comprise at least one switch 141 for selectively assigning the comparator voltage V_{comp} and/or the ramp voltage Vᵣₐₘₚ to the comparator 136. The switch control 140 may be configured for assigning the comparator voltage V_{comp} and/or the ramp voltage Vᵣₐₘₚ to the comparator 136. Specifically, the switch control 140 may be configured for assigning the comparator voltage V_{comp} to the comparator 136, when the comparator 136 is used for determining saturation events 126. Specifically, the switch control 140 may be configured for assigning the ramp voltage Vᵣₐₘₚ to the comparator 136, when the comparator 136 is used for digitizing the analog voltage remainder 120. Generally, other embodiments of the readout circuit 110, such as other interconnections of components of the readout circuit 110 or further components of the readout circuit 110, may also be feasible.

FIG. 2B shows a voltage diagram during a readout using the readout-circuit 110 as shown in FIG. 2A. The top row of the diagram indicates a present control state of the readout circuit 110. At first, an initialization of the readout-circuit 110 may take place. An initialization state is denoted with reference number 164 in FIG. 2B. In the initialization state 162, the MSB counter 144 and the LSB counter 148 may be reset, as indicated in the second row of the diagram, and the IAF clock 162 may be switched on. The reset of the MSB counter 144 and the LSB counter 148 is denoted with reference number 166 in FIG. 2B. Together with the IAF clock 162, a first subordinate integrator clock 168 and a second subordinate integrator clock 170 may be started. The initialization state 164 may be followed by an integrate-and-fire state (IAF state) 172 and an end state 174. The IAF state 172 and the end state 174 may cover an integration time Tint of the readout-circuit 110, i.e. a time during which integration cycles or, correspondingly, saturation events 126 may be counted, specifically by using the IAF clock 160. At the end state 174, an analog voltage remainder 120 may remain at the integrator 128. Before, an end of the IAF state 172 may be represented by the first subordinate integrator clock 160. An end of the end state 174 may be represented by the second subordinate integrator clock 170. After the end state 174, a stop state 176 may follow, in which the IAF clock 160 may be switched off. Up to and including the stop state 176, the comparator voltage V_{comp} may be applied to the comparator 136. Thus, the analog sensor charge 112 may be integrated between the reference voltage V_{ref} and V_{comp} giving out the integration voltage Vᵢₙₜ. Each integration cycle may yield a countable saturation event 126 and at a final unfinished integration cycle the analog voltage remainder 120 may remain at the integrator 128 as outlined above. The stop state 178 may be followed by an analog-to-digital-converter state (ADC state) 178. At the ADC state 178, the ramp voltage Vᵣₐₘₚ may be applied to the comparator 136. Vᵣₐₘₚ may be increased over time until it is equal to the analog voltage remainder 120, which may again trigger an event signal. However, now the ADC counter 162 may be used for digitizing the signal. Finally, a readout state 180 may follow for giving out the determined digital output count 114, wherein V_{comp} is again applied to the comparator 136 and Vᵢₙₜ is reset to V_{ref} as initially the case.

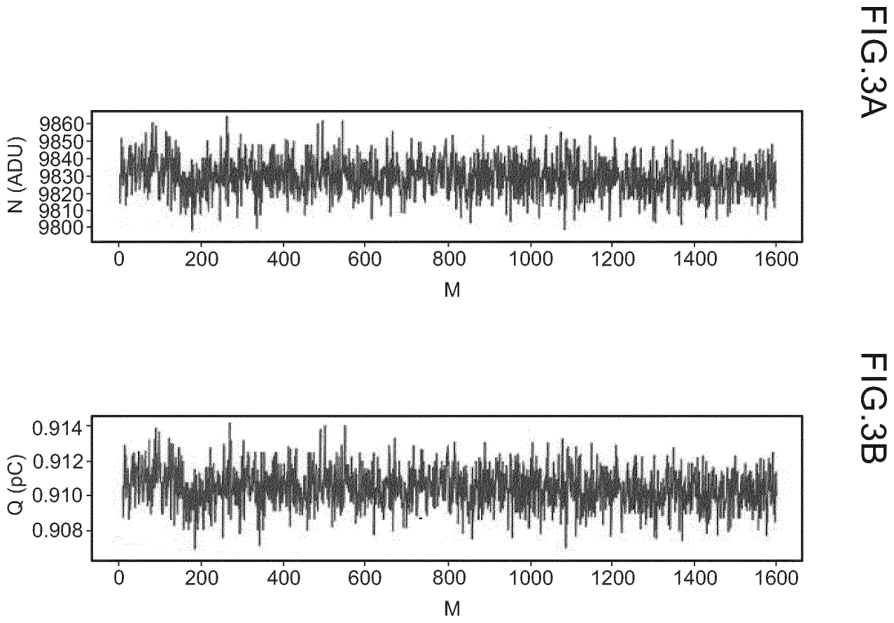

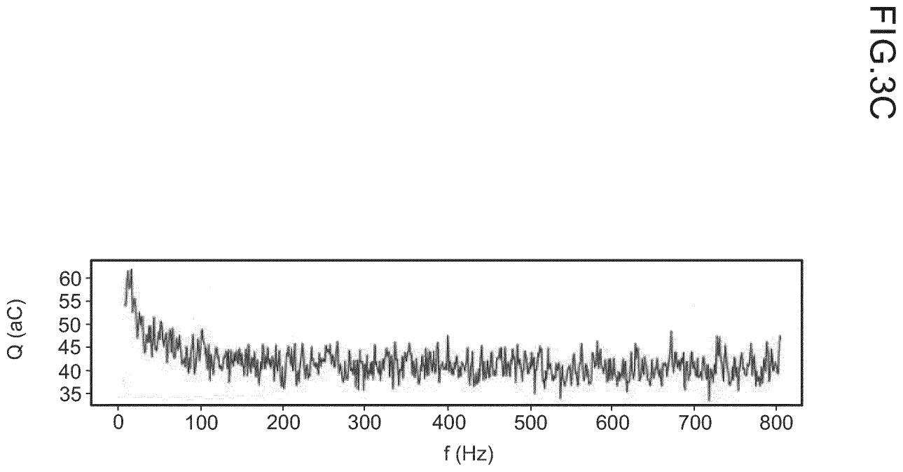

FIGS. 3A-3B show experimental results of measurements on an exemplary embodiment of a readout-circuit 110. Experiments have been made using a prototype system that has implemented the described readout-circuit 110. An exemplary experiment is shown to illustrate the described readout-circuit 110 and it's advantages. The prototype system uses an IAF-circuit 116 followed by an 8-bit counter-type ADC 122. FIG. 3A shows 1600 measurements M with a 1600 Hz sample frequency, wherein each measurement M resulted in a measured ADC count N. An average ADC output p of 9830 counts imply IAF counts of 38, or effectively 5.25 bits of resolution. The experiment displayed a 9.9 count standard deviation σ. The implied signal-to-noise-ration (SNR) based on mean and standard deviation is 992 or effectively 9.96 bits. The effective gain of 4.7-bits of resolution is due to the measurement of the analog voltage remainder 120 utilizing the 8-bit counter-type ADC 122. The IAF-circuit 116 used a capacitor 132 with 50fF to integrate the charge over 500ρs. Calculating the measurement in terms of charge Q implied 0.9pC per sample as shown in FIG. 3B. A Discrete Fourier Transform (DFT) analysis of the measurement is shown in FIG. 3C. The root-mean-square (RMS) charge noise at 16 Hz has been measured to be 58aC. At a frequency f of 160 Hz the RMS charge noise was measured to be 43aC and at 620 Hz the RMS charge noise is 40aC. These noise densities imply an FFT 1-Hz bandwidth SNR of 15.392/VHz at 16 Hz, 20.999/VHz at 160 Hz and 22.449/VHz at 620 Hz. The effective number of bits is therefore 13.9, 14.4, 14.5 at 16 Hz, 160 Hz and 620 Hz respectively.

The readout-circuit 110 has been shown to increase the SNR from 5.25-bits to 9.96-bits effective resolution based on a full-bandwidth analysis of the ADC output. Analysis of the input analog sensor charge 112 shows a noise measurement floor of 40aCᵣₘₛ up to 58aCᵣₘₛ of charge per square root Hertz of bandwidth. The measurement charge of 0.9pC is sufficient for infrared sensors such as PbS or InGaAs with smaller dimensions suitable for array or matrix type of structures. The FFT 1-Hz SNR measurement shows approximately 15 effective bits of measurement. The readout-circuit 110 was implemented with 64 independent ADC measurement channels for parallel readout of 64 sensor elements and utilized an average of 62μW of power per channel. An ADC resolution of 8-bit up to 24-bit has been demonstrated an INL and DNL linearity of <1-LSB. The resolution of the readout-circuit 110 was improved significantly utilizing the 8-bit counter-type ADC 120 instead of a mere IAF current counter approach. Compared to a classic approach using ROICs and ADCs, the power requirements of the readout-circuit 110 were a factor 100 less than for state-of-the-art analog-front-ends (AFEs), such as AFEs of Texas Instruments Inc. or Analog Devices Inc.

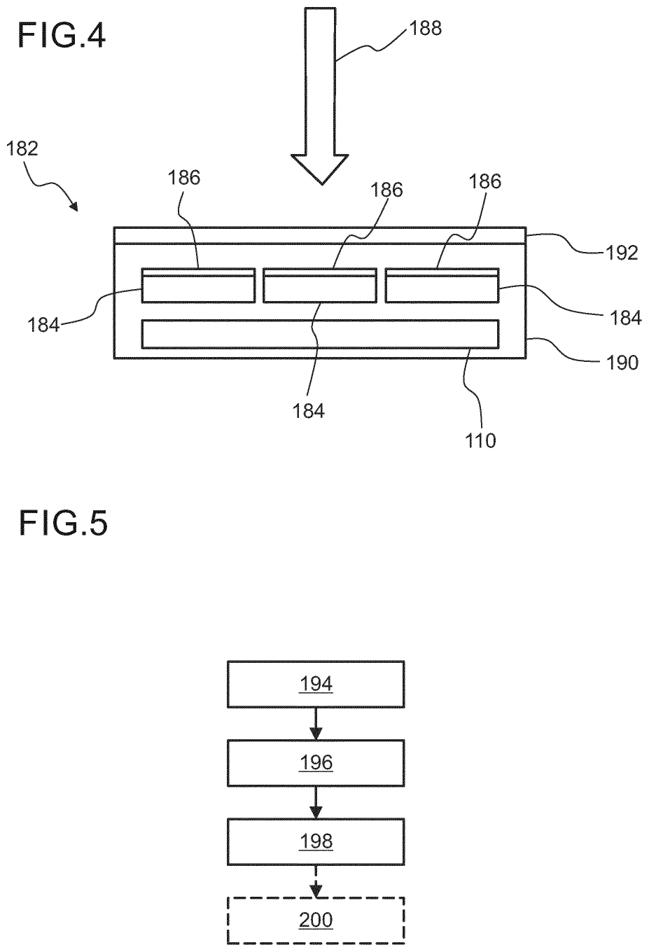

FIG. 4 shows exemplary embodiment of a photodetector 182. The photodetector may be and/or may comprise a photoconductor or a photodiode. The photodetector 182 comprises at least one sensor 184 configured for generating an analog sensor charge 112 dependent on an illumination of a light-sensitive region 186 of the sensor 184. The photodetector 182 comprises at least one readout-circuit 110 according to any one of the embodiments disclosed above or below referring to a readout-circuit 110 in further detail. The photodetector 182 may be a measurement device configured for detecting optical radiation, such as for detecting an illumination and/or a light spot generated by at least one light beam 188. The photodetector 182 may comprise at least one substrate. A single photodetector 182 may be a substrate with at least one single light-sensitive region 186, which generates a physical response to the illumination for a given wavelength range. The photodetector 182 may comprise at least one housing 190 surrounding at least one component of the photodetector 182, such as at least one sensor 184 or readout-circuit 110. The housing 190 may comprise at least one window 192 for transmitting the optical radiation, such as the light beam 188, specifically to at least one sensor 184.

The sensor 184 may be an arbitrary element or device configured for detecting at least one condition or for measuring at least one measurement variable. The sensor 184 may be a light-sensitive sensor 184 as e.g. used in the photodetector 182. Specifically, the sensor 184 may be capable of generating at least one signal, such as a measurement signal, which is a qualitative or quantitative indicator of the measurement variable and/or measurement property, e.g. of an illumination of the sensor 184. The signal may be or comprise an electrical signal, such as a current or a charge. The light-sensitive region 186 may be an area being sensitive to an illumination, e.g. by the incident light beam 188. For example, the light-sensitive region 186 may be a two-dimensional or three-dimensional region which preferably, but not necessarily, may be continuous and/or may form a continuous region. The light-sensitive region may comprise at least one photoconductive material selected from the group consisting of lead sulfide (PbS); lead selenide (PbSe); mercury cadmium telluride (HgCdTe); cadmium sulfide (CdS); cadmium selenide (CdSe); indium antimonide (InSb); indium arsenide (InAs); indium gallium arsenide (InGaAs); silicon (Si); Silicon Germanium (SiGe); extrinsic semiconductors, organic semiconductors. Specifically, the photodetector 182 may comprise a plurality of sensors 184, wherein the sensors 184 may be arranged in an array.

As said, the readout-circuit 110 may specifically be configured for readout of a small analog sensor charge 112. This may specifically be relevant with respect to a readout of photodetectors 182 or, more specifically, individual sensors 184 of photodetectors 182, which may generate only small photocurrents. The readout-circuit 110 may be configured for readout of at least one sensor 182 configured for generating the analog sensor charge 112 dependent on an illumination of a light-sensitive region 186 of the sensor 184. The readout-circuit 110 may be configured for readout of a plurality of sensors 184 configured for generating the analog sensor charge 112 dependent on an illumination of a light-sensitive region 186 of the sensor 184. The sensors 184 may be arranged in an array. The array may be a spatial arrangement of elements such as the sensors 184. The array may be a one-dimensional array, e.g. a sensor sequence along an axis, or a two-dimensional array, e.g. a sensor matrix. The array may also be a three-dimensional array. The array may be a regular array, e.g. comprising constant distances between elements. The array may be an irregular array, e.g. comprising different distances between elements. The elements within the array may be of the same type or of a different type. As an example, the array may comprise sensors 184 which are light-sensitive for different wavelengths.

The readout-circuit 110 may be a readout integrated circuit (ROIC). The readout-circuit 110 may be an integrated circuit (IC), also referred to as chip or microchip, or the readout-circuit 110 may at least form a part of an IC. As the skilled person will know, an IC typically comprises at least one electric circuit assembled on a substrate, specifically a semiconductor substrate, more specifically a silicon (Si) substrate. The readout-circuit 110 may be configured for accumulating at least one sensor current, specifically a photocurrent, wherein the accumulating of the sensor current may generate an analog sensor charge 112. The readout-circuit 110 may be configured for accumulating a photocurrent for each sensor 184 of a photodetector 182 or for groups of sensors 184 of the photodetector 182. The readout-circuit 110 may be configured for storing or at least for buffering the analog sensor charge 112. The readout-circuit 110 may be configured for transferring the analog sensor charge 112 to at least one output, e.g. an output of an IC, wherein the output may specifically be a digital output. The readout-circuit 110 may be a digital readout integrated circuit (DROIC). The DROIC may use on-chip analog-to-digital conversion, specifically for digitizing at least one accumulated photocurrent. The readout-circuit 110 may be a digital pixel readout integrated circuit (DPROIC). The DPROIC uses on-chip analog-to-digital conversion within each pixel or group of pixels, specifically for digitizing at least one accumulated photocurrent, wherein a pixel may specifically refer to a sensor 184 of a photodetector 182.

FIG. 5 shows a flow chart of an exemplary embodiment of a method for readout of an analog sensor charge 112. The method comprises:
a) (denoted with reference number 194) providing at least one readout-circuit 110 according to any one of the embodiments disclosed above or below in further detail referring to a readout-circuit 110;
b) (denoted with reference number 196) converting the analog sensor charge 112 into a first digital output count 118 and an analog voltage remainder 120 by using the IAF-circuit 116; and
c) (denoted with reference number 198) converting the analog voltage remainder 120 into a second digital output 124 by using the ADC 122.

The method may further comprise:
d) (denoted with reference number 200) determining a combined digital output count 118 by combining the first digital output count 118 and the second digital output 124.

The method may comprise further method steps which are not listed. Further, one or more of the method steps may be performed once or repeatedly. Further, two or more of the method steps may be performed simultaneously or in a timely overlapping fashion. The readout may comprise a readout of at least one sensor 184 of at least one photodetector 182 according to any of the embodiments disclosed above or below in further detail referring to a photodetector 182. A resolution of the readout may be controlled by varying a resolution of the second digital output 124 in step c). A gain, specifically a charge-to-voltage gain, of the readout may be controlled by varying a resolution of the second digital output 124 in step c).

### LIST OF REFERENCE NUMBERS

110 readout-circuit
112 analog sensor charge
114 digital output count
116 integrate-and-fire-circuit (IAF-circuit)
118 first digital output count
120 analog voltage remainder
122 analog-to-digital-converter (ADC)
124 second digital output
126 event
128 integrator
130 operational amplifier
132 capacitor
134 mixed signal circuit
136 comparator
138 Schmitt-trigger
140 switch control
141 switch
142 counter
144 most significant bits counter (MSB counter)
146 shutter
148 least significant bits counter (LSB counter)
150 clock
152 output unit
154 transmission gate
156 capacitive trans-impedance amplifier (CTIA)
158 event handler
160 integrate-and-fire clock (IAF clock)
162 analog-to-digital-converter clock (ADC clock)
164 initialization state
166 reset
168 first subordinate integrator clock
170 second subordinate integrator clock
172 integrate-and-fire state (IAF state)
174 end state
176 stop state
178 analog-to-digital-converter state (ADC state)
180 readout state
182 photodetector
184 sensor
186 light-sensitive region
188 light beam
190 housing
192 window
194 step a)
196 step b)
198 step c)
200 step d)

1. A readout-circuit configured for converting an analog sensor charge into a digital output count, wherein the readout-circuit comprises at least one integrate-and-fire(IAF)-circuit, wherein the IAF-circuit is configured for converting the analog sensor charge into a first digital output count, wherein the readout-circuit is further configured for processing an analog voltage remainder after a final IAF cycle, wherein the readout-circuit comprises at least one analog-to-digital-converter (ADC), wherein the ADC is configured for converting the analog voltage remainder into a second digital output.

2. The readout-circuit according to claim 1, wherein the readout-circuit is configured for readout of a small analog sensor charge.

3. The readout-circuit according to claim 1, wherein the readout-circuit is configured for readout of at least one sensor configured for generating the analog sensor charge dependent on an illumination of a light-sensitive region of the sensor.

4. The readout-circuit according to claim 1, wherein the readout-circuit is configured for determining a combined digital output by combining the first digital output count and the second digital output, wherein the first digital output count is proportional to a whole number of integration cycles, wherein the second digital output is proportional to a remainder voltage of a final uncompleted integration cycle.

5. The readout-circuit according to claim 1, wherein the IAF-circuit comprises
at least one integrator, wherein the integrator comprises at least one operational amplifier and at least one capacitor, wherein an input of the operational amplifier is held to a known voltage V_{ref}, wherein the integrator is configured for resetting an output of the operational amplifier is reset to V_{ref} after each saturation event, wherein the integrator is configured for integrating the output of the operational amplifier between the reference voltage V_{ref} and a comparator voltage V_{comp} for determining an integration voltage Vᵢₙₜ;
at least one comparator configured for determining a saturation event;
at least one counter configured for determining the first digital output count by counting the saturation events; and
at least one mixed signal circuit configured for resetting Vᵢₙₜ to V_{ref} after each saturation event.

6. The readout-circuit according to claim 5, wherein the analog voltage remainder is a leftover voltage after a final IAF cycle that has not triggered a saturation event.

7. The readout-circuit according to claim 1, wherein the ADC comprises at least one ADC architecture selected from the group consisting of a counter type ADC, a single-slope ADC, a dual-slope ADC, a pipelined ADC, a successive-approximation (SAR) ADC, and a sigma-delta ADCs.

8. The readout-circuit according to claim 1, wherein the ADC comprises a counter type ADC, wherein the ADC and the IAF-circuit share at least one component.

9. A photodetector comprising
at least one sensor configured for generating an analog sensor charge dependent on an illumination of a light-sensitive region of the sensor; and
at least one readout-circuit according to claim 1.

10. The photodetector according to claim 9, wherein the light-sensitive region comprises at least one photoconductive material selected from the group consisting of lead sulfide (PbS); lead selenide (PbSe); mercury cadmium telluride (HgCdTe); cadmium sulfide (CdS); cadmium selenide (CdSe); indium antimonide (InSb); indium arsenide (InAs); indium gallium arsenide (InGaAs); silicon (Si); Silicon Germanium (SiGe); extrinsic semiconductors, and organic semiconductors.

11. A method for readout of an analog sensor charge, the method comprising
a) providing at least one readout-circuit according to claim 1;
b) converting the analog sensor charge into a first digital output count and an analog voltage remainder by using the IAF-circuit; and
c) converting the analog voltage remainder into a second digital output count by using the ADC.

12. The method according to claim 11, further comprising:
d) determining a combined digital output count by combining the first digital output count and the second digital output.

13. A non-transient computer-readable medium including instructions that, when executed by one or more processors, cause the one or more processors to perform the method according to claim 11.

14. A method of using the readout-circuit according to claim 1, the method comprising using the readout-circuit for readout of one or more of at least one PbS sensor, at least one PbSe sensor, or at least one pixelated sensor array comprising a plurality of pixels, wherein each of the pixels comprises at least one PbS or PbSe sensor.
